(19) United States
(12) Patent Application Publication
(10) Pub. No.: US 2006/0013954 A1
(43) Pub. Date: Jan. 19, 2006

(54) Method for improving atomic layer deposition process and the device thereof

(76) Inventor: Wen-Pin Chiu, Yun Lin Hsien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/952,293

(22) Filed: Sep. 28, 2004

(30) Foreign Application Priority Data
Jul. 16, 2004 (TW) 93121391

(51) Int. Cl. C23C 16/00

(52) U.S. Cl. 427/248.1; 118/719

(57) ABSTRACT

A method for improving an atomic layer deposition process and the device thereof are described. A shield is first formed in a chamber to divide the chamber into a first sub-chamber and a second sub-chamber. Then a first precursor gas and a second precursor gas are introduced into the first sub-chamber and the second sub-chamber, respectively. A wafer is transferred into the first sub-chamber. When the surface of the wafer is saturated with the first precursor gas, the wafer is moved into the second sub-chamber by rotating a spindle, and the first precursor gas reacts with the second precursor gas. Further, the shield is employed to remove the excess first precursor gas and the unreacted second precursor gas. Subsequently, another wafer is transferred into the first sub-chamber, and hence two wafers are treated simultaneously to increase the throughput of the process.

### RELATED APPLICATIONS

The present application is based on, and claims priority from, Taiwan Application Serial Number 93121391, filed Jul. 16, 2004, the disclosure of which is hereby incorporated by reference herein in its entirety.

### FIELD OF THE INVENTION

The present invention relates to a method for improving a semiconductor process and a device thereof, and more particularly, to a method for improving an atomic layer deposition process and a device thereof.

### BACKGROUND OF THE INVENTION

Due to the rapid development of the semiconductor industry various process technologies and applied materials have been greatly developed for continuously enhancing the integration degree and the operation performance of the devices in the integrated circuit. As the device size has been minimized, the aspect ratio of the contact and the via has also greatly increased, resulting in increased difficulty in operating the deposition process. Hence, how a conformal metal layer is formed in the contact and via with the increased aspect ratio has become one of the key subjects in the development of the sub-micron process.

Nowadays, an atomic layer deposition (ALD) process is a popular method for forming a conformal metal layer. Reference is made to FIGS. 1A to 1C, which are cross-sectional diagrams of the wafer during different stages of the atomic layer deposition process according to the prior art. As shown in FIG. 1A, a precursor reactant 120 is introduced into a chamber until the surface of the wafer 100 is saturated with the precursor reactant 120. The excess precursor reactant 120 is then exhausted. Next, as shown in FIGS. 1B and 1C, another precursor reactant 140 is introduced, reacts with the precursor reactant 120 adsorbed on the surface of the wafer 100, and then a product 160 is formed on the surface of the wafer 100. Subsequently, the unreacted precursor reactant 140 and by-product are exhausted. The product 160 is controlled to be a monolayer deposited on the surface of the wafer 100 during the atomic layer deposition process, so the product 160 is conformally formed in the contact or the via. However, the deposition rate of the metal layer is very slow when using the atomic layer deposition process, and the thickness of resultant metal layer is very thin, typically about 0.5 angstroms (Å) to 3 Å. If the thickness of resultant metal layer needs to be several tens of Å, the atomic layer deposition process must be repeated several tens of times, and the throughput is severely affected.

### SUMMARY OF THE INVENTION

Hence, it is an aspect of the present invention to provide a method for improving an atomic layer deposition process and a device thereof, so as to deposit a conformal metal layer and to increase the throughput of the process.

According to the aforementioned aspect of the present invention, a device for improving an atomic layer deposition process is provided, which has a shield for dividing a chamber into a plurality of sub-chambers, a plurality of gas injecting plates disposed correspondingly above the sub-chambers for introducing precursor gases required in different steps into the sub-chambers, and a revolving spindle. The revolving spindle is connected to a plurality of susceptors and rotated to move the susceptors from one sub-chamber into another sub-chamber. A plurality of wafers can be simultaneously transferred into the device to perform the deposition process, and then by rotating operations, the atomic layer deposition process is completed. The desired thickness can be achieved by controlling rotation numbers. Therefore, the operation time of the deposition process can be reduced effectively, so as to increase the throughput of the process.

In addition, a method for improving an atomic layer deposition process is provided, which utilizes a shield that consists essentially of an inert gas to divide a chamber into a plurality of sub-chambers, and introduces precursor gases required in different steps into the sub-chambers. Next, a wafer is transferred into a sub-chamber to perform a gas adsorption step in which the deposition process gases are adsorbed on the surface of the wafer. The wafer is then moved into another sub-chamber to perform a main deposition step. Afterwards, another wafer is transferred into the sub-chamber of the gas adsorption step. Therefore, the gas adsorption step and the film deposition step can be simultaneously performed on a plurality of wafers, so as to increase the throughput and the process effectively. Furthermore, the reaction steps in different stages are performed in different sub-chambers, so the step of changing precursor gases is not necessary. Hence, the operation time and steps of the process can be greatly reduced, and the throughput of the process can be increased effectively.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1C are cross-sectional diagrams of the wafer during different steps of the atomic layer deposition process according to the prior art;

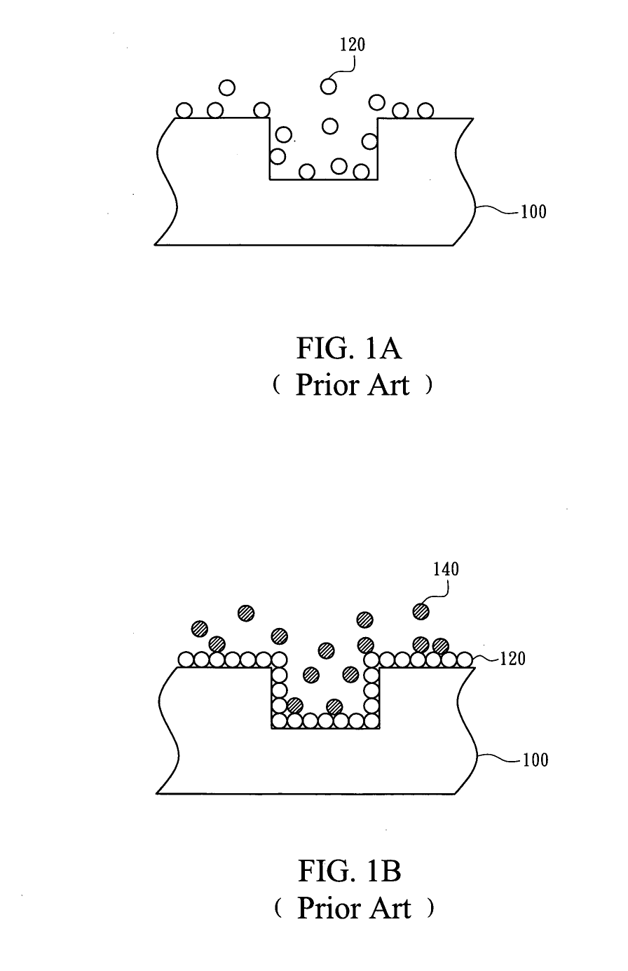

FIG. 2 is a schematic diagram of the device for improving the atomic layer deposition process in accordance with a preferred embodiment of the present invention; and

FIG. 3 is a flow chart of the method for improving the atomic layer deposition process in accordance with a preferred embodiment of the present invention.

### DETAILED DESCRIPTION OF THE PREFERRED EMBODIMENT

In order to increase the throughput of the atomic layer deposition process and more effectively utilize the process precursor gases, the present invention provides a method for improving an atomic layer deposition process and a device thereof. Hereinafter, the preferred embodiments are described in detail with the accompanying drawings.

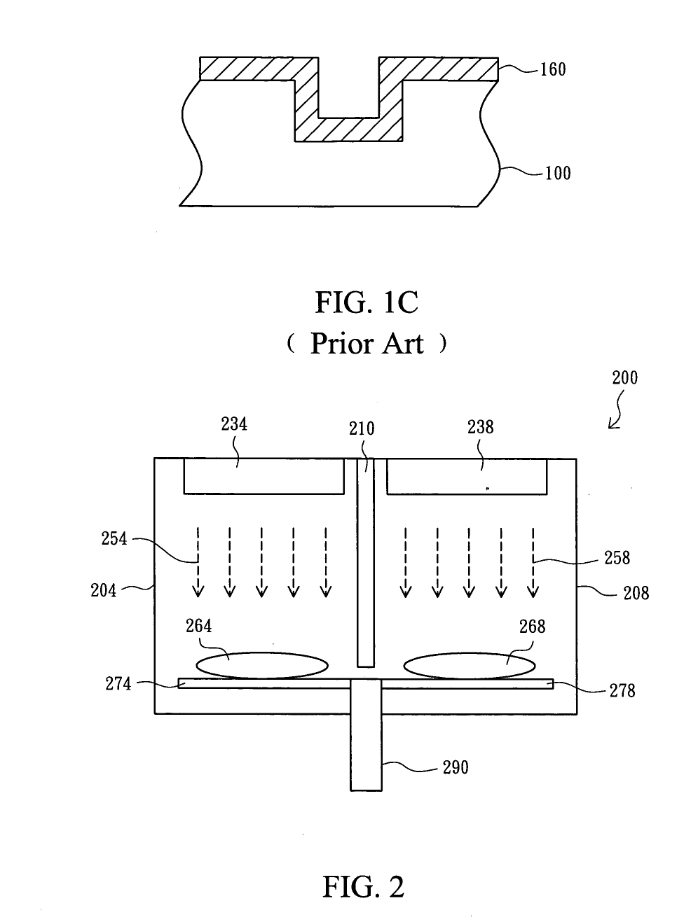

Reference is made to FIG. 2, which is a schematic diagram of the device for improving the atomic layer deposition process in accordance with a preferred embodiment of the present invention. As shown in FIG. 2, a shield 210 is disposed in a chamber 200 and divides the chamber 200 into a first sub-chamber 204 and a second sub-chamber 208. The shield 210 may consist essentially of an inert gas, such as argon (Ar), helium (He) or nitrogen (N₂). A first gas injecting plate 234 and a second gas injecting plate 238 are directly disposed above the first sub-chamber 204 and the second sub-chamber 208, respectively, for introducing a first precursor gas 254 and a second precursor gas 258. A first susceptor 274 and a second susceptor 278 are disposed correspondingly below the first gas injecting plate 234 and the second gas injecting plate 238, respectively. Therefore, a plurality of wafers may be processed simultaneously in the chamber, and different reaction steps may be performed in different sub-chambers. In this preferred embodiment, the first sub-chamber 204 is employed for performing a gas adsorption step of the first precursor gas 254 in the atomic layer deposition process, and the second sub-chamber 208 is employed for performing a main deposition step. In an example of forming a metal tungsten (W) film, the first precursor gas 254 may be a silane (SiH₄) gas, a borane (B₂H₆) gas or a combination thereof, and the second precursor gas 258 may be a tungsten hexafluoride (WF₆) gas. Due to the precursor gas adsorption step and the deposition step are performed in different sub-chambers, respectively, the shield 210 separates and prevents the first precursor gas 254 and the second precursor gas 258 from mixing and contacting with each other. Therefore, it is not necessary to perform the step of exhausting excess precursor gases in the atomic layer deposition process of the prior art. The steps required in the atomic layer deposition process can be effectively reduced, so as to increase the throughput.

In addition, the foregoing device further has a revolving spindle 290 that connects with the first susceptor 274 and the second susceptor 278. After rotating the revolving spindle 290 to an appropriate angle, the first susceptor 274 can be moved from the first sub-chamber 204 into the second sub-chamber 208, and the second susceptor 278 can be moved from the second sub-chamber 208 into the first sub-chamber 204. After a second wafer 268 is transferred to the first sub-chamber 204 and the first precursor gas adsorption step is completed, in other words, the first precursor gas adsorbed on the surface of the second wafer 268 reaches saturation, the spindle 290 is rotated to move the second wafer 268 into the second sub-chamber 208 to perform a deposition step; and simultaneously, the first wafer 264 is transferred into the first sub-chamber 204 to perform the gas adsorption step of the first precursor gas 254. Hence, by controlling the revolving spindle 290, a plurality of wafers perform the gas adsorption step and the deposition step continuously and in turn until the desired thickness of the metal layer is obtained. Moreover, the shield 210 consisting essentially of the inert gas is not only employed for preventing the first precursor gas 254 and the second precursor gas 258 from mixing with each other but also employed for removing the unreacted precursor gas on the wafer. For example, when the second wafer 268 is moved from the first sub-chamber 204 into the second sub-chamber 208, the unreacted first precursor gas 254 on the second wafer 268 can be removed, and when the second wafer 268 is moved from the second sub-chamber 208 into the first sub-chamber 204, the second precursor gas 258 that is unreacted with the first precursor gas 254 on the second wafer 268 can be removed. As a result, an additional removal step is not necessary, and the operation time of the process can be greatly reduced, thereby increasing throughput.

In the aforementioned preferred embodiment, the chamber is divided into the first sub-chamber and the second sub-chamber; however, a plurality of shields can be further disposed in the chamber to divide the chamber into a plurality of the first sub-chambers and a plurality of the second sub-chambers depending on the size of the chamber and the requirement of the process. By controlling the revolving spindle, a plurality of wafers perform the gas adsorption step and the deposition step in the first sub-chamber and the second sub-chamber continuously and in turn for increasing the throughput and the process effectively. Therefore, the present invention is not limited herein.

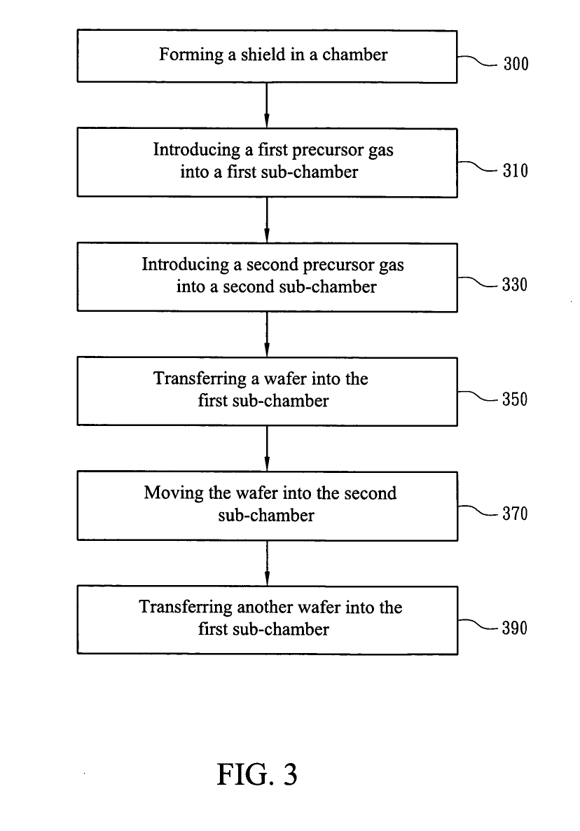

Reference is made to FIG. 3, which is a flow chart of the method for improving the atomic layer deposition process in accordance with a preferred embodiment of the present invention. As shown in FIG. 3, the step 300 is first performed, which introduces an inert gas to form at least one shield in a chamber, and the shield divides the chamber into at least one first sub-chamber and at least one second sub-chamber, wherein the inert gas is selected from the group consisting of argon, nitrogen and helium. Next, the step 310 and the step 330 are performed, which introduce a first precursor gas and a second precursor gas into the first sub-chamber and the second sub-chamber, respectively, to perform an atomic layer deposition process. And then in the step 350, a wafer is transferred into the first sub-chamber to perform the first precursor gas adsorption step. After the surface of the wafer is saturated with the first precursor gas, a spindle is rotated to move the wafer into the second sub-chamber in the step 370, and the adsorbed first precursor gas reacts with the adsorbed second precursor gas to form a film. In addition, the inert gas is also employed to remove the unreacted first precursor gas and the unreacted second precursor gas on the surface of the wafer. Afterward, another wafer is transferred into the first sub-chamber, for simultaneously processing a plurality of wafers to increase the operation rate of the process. Besides, the step 350 and the step 370 can be repeated to increase the deposition thickness of the film.

Therefore, according to the aforementioned preferred embodiments, one advantage of the method for improving an atomic layer deposition process and the device thereof is that the first precursor gas adsorption and the film deposition can be simultaneously performed on a plurality of wafers, thereby increasing the throughput and the process effectively. Moreover, the gas adsorption step and the deposition step are performed in different sub-chambers, respectively, so it is not necessary to change the precursor gases required in different steps repeatedly, thereby effectively reducing the step of changing precursor gases. Furthermore, when the wafers are reciprocated between the sub-chambers, the shield consisting essentially of the inert gas is employed for removing the unreacted precursor gas on the wafer. Therefore, the operation time of the atomic layer deposition process can be greatly reduced, increasing the throughput.

As is understood by a person skilled in the art, the foregoing preferred embodiments of the present invention are illustrative rather than limiting of the present invention. It is intended that various modifications and similar arrangements be included within the spirit and scope of the appended claims, the scope of which should be accorded the broadest interpretation so as to encompass all such modifications and similar structure.

What is claimed is:

1. A method for improving an atomic layer deposition process, comprising:
forming at least one shield in a chamber, wherein the shield divides the chamber into at least one first sub-chamber and at least one second sub-chamber;
introducing a first precursor gas into the first sub-chamber;
introducing a second precursor gas into the second sub-chamber;
transferring a wafer into the first sub-chamber; and
moving the wafer into the second sub-chamber.

2. The method for improving an atomic layer deposition process according to claim 1, further comprising:
transferring another wafer into the first sub-chamber.

3. The method for improving an atomic layer deposition process according to claim 1, further comprising:
moving the wafer repeatedly between the first sub-chamber and the second sub-chamber, so as to achieve a desired deposited thickness of the atomic layer.

4. The method for improving an atomic layer deposition process according to claim 1, wherein an inert gas is introduced into the chamber for forming the at least one shield.

5. The method for improving an atomic layer deposition process according to claim 4, wherein the inert gas is selected from the group consisting of argon, nitrogen and helium.

6. The method for improving an atomic layer deposition process according to claim 1, wherein during moving the wafer into the second sub-chamber, the shield is employed to remove the first precursor gas that is unadsorbed on the wafer.

7. The method for improving an atomic layer deposition process according to claim 1, wherein the wafer is moved into the second sub-chamber by rotating a spindle to move a susceptor for supporting the wafer from the first sub-chamber into the second sub-chamber.

8. The method for improving an atomic layer deposition process according to claim 1, wherein the first precursor gas is a silane (SiH₄) gas, a borane (B₂H₆) gas or a combination thereof.

9. The method for improving an atomic layer deposition process according to claim 1, wherein the second precursor gas is a tungsten hexafluoride (WF₆) gas.

10. A method for increasing a throughput of an atomic layer deposition process, comprising:
introducing an inert gas into a chamber for forming at least one shield, and the shield divides the chamber into at least one first sub-chamber and at least one second sub-chamber;
introducing a first precursor gas into the first sub-chamber;
introducing a second precursor gas into the second sub-chamber;
transferring a wafer into the first sub-chamber; and
rotating a spindle to move the wafer from the first sub-chamber into the second sub-chamber.

11. The method for increasing a throughput of an atomic layer deposition process according to claim 10, further comprising:
transferring another wafer into the first sub-chamber.

12. The method for increasing a throughput of an atomic layer deposition process according to claim 10, further comprising:
moving the wafer repeatedly between the first sub-chamber and the second sub-chamber, so as to achieve a desired deposited thickness of the atomic layer.

13. The method for increasing a throughput of an atomic layer deposition process according to claim 10, wherein the inert gas is selected from the group consisting of argon, nitrogen and helium.

14. The method for increasing a throughput of an atomic layer deposition process according to claim 10, wherein the inert gas is employed to remove the first precursor gas and the second precursor gas that are unreacted on the wafer.

15. The method for increasing a throughput of an atomic layer deposition process according to claim 10, wherein the first precursor gas is a silane gas, a borane gas or a combination thereof.

16. The method for increasing a throughput of an atomic layer deposition process according to claim 10, wherein the second precursor gas is a tungsten hexafluoride (WF₆) gas.

17. A device for improving an atomic layer deposition process, comprising:
at least one shield formed in a chamber for dividing the chamber into at least one first sub-chamber and at least one second sub-chamber;
at least one first gas injecting plate directly disposed above the first sub-chamber for introducing a first precursor gas;
at least one second gas injecting plate directly disposed above the second sub-chamber for introducing a second precursor gas; and
a revolving spindle connected to at least one first susceptor and at least one second susceptor disposed correspondingly below the first gas injecting plate and the second gas injecting plate, respectively, wherein after a wafer is disposed on the first susceptor and the first precursor gas is introduced for a period of time, the revolving spindle is rotated to move the wafer from the first sub-chamber into the second sub-chamber.

18. The device for improving an atomic layer deposition process according to claim 17, wherein the shield consists essentially of an inert gas.

19. The device for improving an atomic layer deposition process according to claim 18, wherein the inert gas is selected from the group consisting of argon, nitrogen and helium.

20. The device for improving an atomic layer deposition process according to claim 17, wherein the first precursor gas is a silane gas, a borane gas or a combination thereof.

21. The device for improving an atomic layer deposition process according to claim 17, wherein the second precursor gas is a tungsten hexafluoride (WF₆) gas.
